(19) United States
(12) Patent Application Publication
(10) Pub. No.: US 2005/0016452 A1
(43) Pub. Date: Jan. 27, 2005

(54) Gas supply unit and semiconductor device manufacturing apparatus using the same

(75) Inventors: Sung-Won Ryu, Yongin-city (KR); Yeon-Sik Park, Suwon-city (KR)

Correspondence Address: Steven M. Mills;MILLS & ONELLO LLP, Suite 605, Eleven Beacon Street, Boston, MA, 02108, US

(73) Assignee: Samsung Electronics Co., Ltd.

(21) Appl. No.: 10/830,603

(22) Filed: Apr. 23, 2004

(30) Foreign Application Priority Data
Jul. 22, 2003 (KR) 03-50366

(51) Int. Cl. C23C 16/00

(52) U.S. Cl. 118/715

(57) ABSTRACT

A semiconductor device manufacturing apparatus is provided. The semiconductor device manufacturing apparatus comprises a furnace having a closed predetermined space for seating a wafer, a loading device located at one side of the furnace to load the wafer on which a prior process may have been performed, a gate valve interposed between the furnace and the loading device to selectively open/close a pathway between the furnace and the loading device, a heater for heating an interior of the furnace, a vacuum pump for maintaining the interior of the furnace with a suitable pressure necessary to the process, a gas reservoir for storing individually various kinds of reaction gases supplied from an exterior of the space, a gas mixing device connected to the gas reservoir to mix the various kinds of reaction gases supplied from the gas reservoir with an even mixing ratio, at least two mixed gases supply pipes connected to the gas mixing device to supply the reaction gases mixed in the gas mixing device to each direction of the furnace, and a mixed gases flow control unit installed at the mixed gases supply pipe to control the flow of the reaction gases supplied through the mixed gases supply pipe.

This U.S. nonprovisional patent application claims priority under 35 U.S.C. § 119 of Korean Patent Application 2003-50366 filed on Jul. 22, 2003, the entire contents of which are hereby incorporated by reference.

### BACKGROUND OF THE INVENTION

1. Field of the Invention

The present invention relates to a semiconductor device manufacturing apparatus and, more particularly, to a semiconductor device manufacturing apparatus for depositing a predetermined thin-film on an upper surface of a wafer using a chemical vapor deposition method.

2. Description of the Related Art

Generally, a semiconductor device is manufactured by repeating a process of stacking a number of thin-films into multi-layers on an upper surface of a pure silicon wafer. Therefore, a semiconductor device manufacturing process essentially includes a thin-film deposition process for depositing a predetermined thin-film on an upper surface of a wafer.

The thin-film deposition process is conventionally classified into a physical vapor deposition method and a chemical vapor deposition method depending upon a thin-film deposition method.

The chemical vapor deposition method is performed by successively supplying certain reaction gases to the interior of a closed space such as a chamber or a furnace while prescribed process conditions, such as process temperature, pressure, etc., are maintained in the closed inner space. As a result, the wafer in the closed predetermined space has a predetermined thickness of thin-film deposited by a powder formed as the reaction gases supplied into the certain process conditions are chemically resolved.

Also, a supply flow of certain reaction gases necessary to a process should be controlled precisely depending upon various kinds of thin-films to be deposited in order to implement the thin-film deposition process using the chemical vapor deposition.

Various methods for attempting to precisely control the supply flow of the reaction gases have been used.

As an example of the methods, Japanese Laid-open Patent Publication No. 2002-231708 (Publication-Date: Aug. 16, 2002, Title: Coating film processing apparatus and method thereof) has been disclosed.

Referring to the '708 patent, a chamber for seating a wafer and a plurality of mass flow controllers (hereinafter referred to as “MFC”) for precisely controlling the supply flow of reaction gases into the interior of the chamber are provided.

In case of the '708 patent, when the certain reaction gases, i.e., an ammonia gas (NH3) and a humidified nitrogen gas (H2O/N2) necessary to the process are supplied from the exterior, the plurality of MFCs precisely control overall supply flow of the ammonia gas and the humidified nitrogen gas to evenly supply the gases to one side direction and the other side direction of the chamber at which each wafer is seated.

Although the supply flow control of the reaction gases can wholly control the flow of the reaction gases supplied into the interior of the chamber, there is a drawback that the control cannot be performed when a flow control of individual reaction gases supplied into one side direction and the other side direction of the chamber is required.

For example, among processes of depositing predetermined thin-films on the upper surface of the wafer using chemical vapor deposition, there is a thin-film deposition process of depositing a thin-film of SiGe on a number of wafers under an ultra high vacuum.

The SiGe thin-film deposition process is very sensitive in that the flow of the reaction gases should be gradually increased to a certain flow as time passes, and, after a given time is passed, the flow of the reaction gases should be slowly decreased to below a certain flow. This is in contrast to providing the reaction gases at an even flow being continuously supplied from start to finish of the process.

Therefore, the conventional SiGe thin-film deposition process is accomplished by a semiconductor device manufacturing apparatus provided with a horizontal furnace seating a number of wafers arranged in a wafer boat, and a gas supply unit for supplying predetermined reaction gases to one side direction and the other side direction of the horizontal furnace.

When certain reaction gases are supplied from the exterior in the case of a conventional semiconductor device manufacturing apparatus, the gas supply unit employs the MFC to control gas supply flow necessary to the process entirely, after the control, to supply the gases evenly to one side direction and the other side direction of the furnace.

However, the flow control of the entire reaction gases using the conventional MFC has a problem that a smooth progress of the process is difficult since a composition rate of the reaction gases is very important due to characteristics of the SiGe thin-film deposition process.

### SUMMARY OF THE INVENTION

Therefore, to solve the problem described hereinabove, an object of the present invention is to provide a gas supply unit capable of precisely controlling a supply flow of reaction gases supplied into the interior of a closed predetermined space such as a chamber or a furnace and a semiconductor device manufacturing apparatus using the same.

Another object of the present invention is to provide a gas supply unit capable of individually controlling and monitoring each supply flow of reaction gases supplied into the interior of a closed predetermined space through different angular directions and a semiconductor device manufacturing apparatus using the same.

A semiconductor device manufacturing apparatus in accordance with a first aspect of the present invention comprises a furnace having a closed space for seating a wafer, a loading device located at one side of the furnace to load the wafer to an interior of the furnace, a gate valve interposed between the furnace and the loading device to selectively open/close a pathway between the. furnace and the loading device, a heater at a surface of the furnace for heating the interior of the furnace, a vacuum pump at an exterior surface of the furnace for maintaining a pressure in the interior of the furnace, a gas reservoir for individually storing various reaction gases supplied from the exterior of the furnace, a gas mixing device connected to the gas reservoir to mix the various reaction gases supplied from the gas reservoir, at least two mixed gases supply pipes connected to the gas mixing device to supply the reaction gases mixed in the gas mixing device in each of a plurality of directions in the furnace, and a mixed gases flow control unit installed at the mixed gases supply pipes to control the flow of the reaction gases supplied through the mixed gases supply pipe.

In one embodiment, the gas mixing device mixes the various reaction gases with an even mixing ratio.

The mixed gases flow control unit can include a flow control valve installed at the mixed gases supply pipe to control the flow of the reaction gases, and a mass flow meter (hereinafter referred to as “MFM”) installed at the mixed gases supply pipe to measure the flow of the reaction gases.

Further, the mixed gases flow control unit can include an open/close valve for selectively opening/closing the mixed gases supply pipe.

The mass flow meter can be installed at the mixed gases supply pipe between the furnace and the flow control valve

In addition, the flow control valve can include a needle valve.

Further, the interior of the furnace can include a pressure sensor for measuring a pressure of an interior of the furnace.

In one embodiment, the gas reservoir comprises a number of gas bottles for individually storing the various reaction gases supplied from the exterior of the furnace, and a number of single gas supply pipes for transmitting the reaction gases stored in the number of gas bottles to the gas mixing device, respectively.

In one embodiment, the gas mixing device comprises a number of mass flow controllers individually installed at the number of single gas supply pipes to respectively control the flow of the reaction gases supplied through the single gas supply pipe, and a gas mixing unit for mixing the reaction gases flow controlled through the mass flow controller.

A gas supply unit in accordance with a second aspect of the present invention comprises a gas reservoir installed at a side of a chamber for a predetermined processing space to store individually the various reaction gases, a gas mixing device connected to the gas reservoir to mix the various reaction gases supplied from the gas reservoir , at least two mixed gases supply pipes connected to the gas mixing device to supply the reaction gases mixed in the gas mixing device in each of a plurality of directions in the chamber, and a mixed gases flow control unit installed at the mixed gases supply pipe to control the flow of the reaction gases supplied through the mixed gases supply pipe.

The mixed gases flow control unit can include a flow control valve installed at the mixed gases supply pipe to control the flow of the reaction gases, and a mass flow meter installed at the mixed gases supply pipe to measure the flow of the reaction gases.

Further, the mixed gases flow control unit can include an open/close valve for selectively opening/closing the mixed gases supply pipe.

The mass flow meter can be installed at the mixed gases supply pipe between the chamber and the flow control valve.

The flow control valve can be a needle valve.

The gas reservoir can include a number of gas bottles for storing the various reaction gases supplied from the exterior of the gas supply unit individually, and a number of single gas supply pipes for transmitting the reaction gases stored in the number of gas bottles to the gas mixing device, respectively.

In one embodiment, the gas mixing device comprises a number of mass flow controllers individually installed at the number of single gas supply pipes to respectively control the flow of the reaction gases supplied through the single gas supply pipe, and a gas mixing unit for mixing the reaction gases flow controlled through the mass flow controller.

In one embodiment, the gas mixing device mixes the various reaction gases with an even mixing ratio.

### BRIEF DESCRIPTION OF THE DRAWINGS

The foregoing and other objects, features and advantages of the invention will be apparent from the more particular description of a preferred embodiment of the invention, as illustrated in the accompanying drawing. The drawing is not necessarily to scale, emphasis instead being placed upon illustrating the principles of the invention.

FIG. 1 is a structural view schematically illustrating an embodiment of a semiconductor device manufacturing apparatus in accordance with the present invention.

### DETAILED DESCRIPTION OF THE PREFERRED EMBODIMENT

Hereinafter, the detailed description of a preferred embodiment of a gas supply unit 120 and a semiconductor device manufacturing apparatus 100 in accordance with the present invention will be apparent in connection with the accompanying drawing.

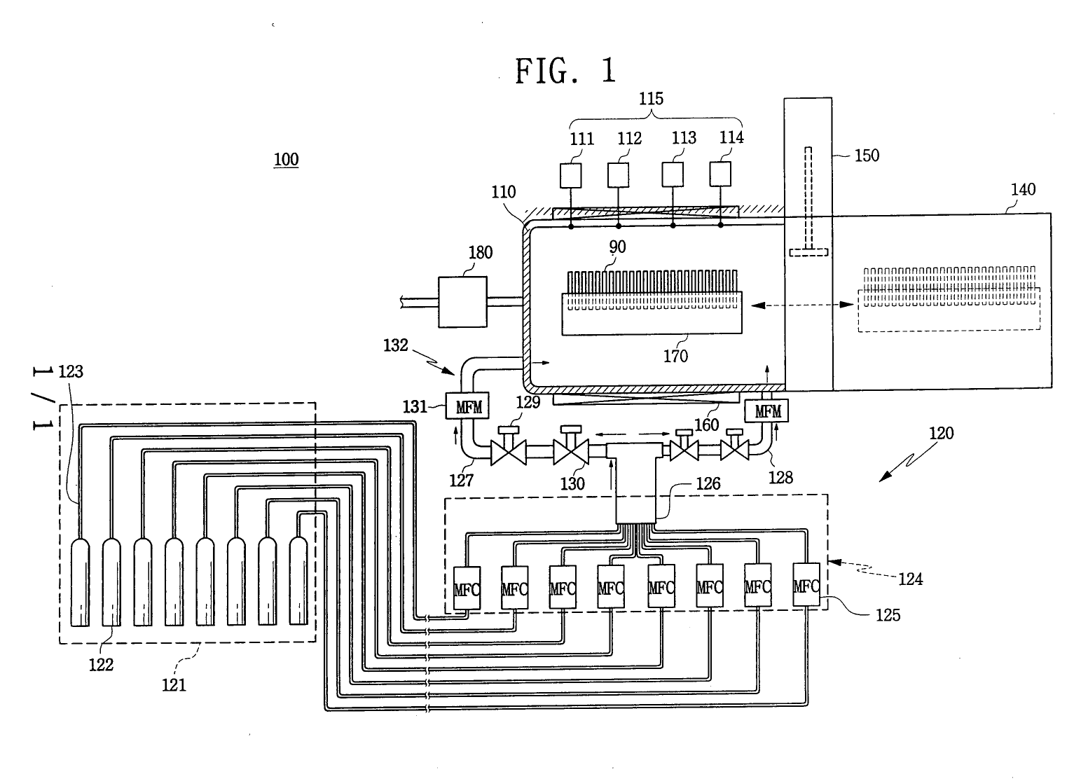

The semiconductor device manufacturing apparatus 100 in accordance with the present invention, as shown in FIG. 1, comprises a wafer boat 170 in which a number of wafers 90 are arranged sequentially. A furnace 110 has a closed predetermined space or chamber for seating the wafer boat 170 to deposit a predetermined thin-film on an upper surfaces of the wafers 90 arranged in the wafer boat 170. A loading part or member 140 is located at one side of the furnace 110 to load the wafers 90 that have undergone a prior process. A gate valve 150 is interposed between the furnace 110 and the loading part 140 to selectively open/close a pathway through which the wafer boat 170 is transferred between the furnace 110 and the loading part 140. A central control unit (not shown) controls the semiconductor device manufacturing apparatus 100.

The furnace 110 is depicted as a horizontal furnace for forming and maintaining uniform process conditions for generating a predetermined thin-film deposition reaction. The horizontal furnace comprises a heater 160, a vacuum pump 180, a number of pressure sensors 115, and a gas supply unit 120 for creating and maintaining uniform process conditions in the interior of the horizontal furnace with.

More specifically, the heater 160 is installed at a peripheral surface of the furnace 110 to accomplish a function of heating the inside of the furnace 110 to a suitable temperature.

The vacuum pump 180 is installed at one side of an exterior of the furnace 110 to accomplish a function of maintaining the inside of the furnace 110 with a suitable pressure necessary to the process, and is shown embodied as a turbo pump etc.

Further, the number of pressure sensors 115 are installed at one side of the inside of the furnace 110 to accomplish a function of precisely detecting a pressure of the inside of the furnace 110. The pressure sensors iniclude a first pressure sensor 111 for detecting when an inner pressure of the furnace 110 is atmospheric pressure, a second pressure sensor 112 for detecting when an inner pressure of the furnace is in a range from atmospheric pressure to 10⁻³ mmHg, a third pressure sensor 113 for detecting when an inner pressure of the furnace 110 is in a range from 10⁻² mmHg to 10⁻⁵ mmHg, and a fourth pressure sensor 114 for detecting when an inner pressure of the furnace is in a range from 10⁻⁴ mmHg to 10⁻⁹ mmHg.

The gas supply unit 120 in accordance with the present invention is connected to one exterior surface of the furnace 110 to accomplish a function of receiving certain reaction gases necessary to the process from the exterior and supplying the gases to the inside of the furnace 110.

Therefore, the gas supply unit 120 comprises a gas reservoir 121 for receiving the various kinds of reaction gases from the exterior and storing the gases individually. A gas mixing part or member 124 mixes the various reaction gases with a predetermined mixing ratio suitable for the process, and a gas supply part or member 132 supplies the mixed reaction gases (hereinafter referred to as “mixed gases”) to the inside of the furnace 110.

The gas reservoir 121 comprises a number of gas bottles 122 for storing the various kinds of single reaction gases (hereinafter referred to as “single gas”) individually, and a number of single gas supply pipes 123 for transmitting the single gases in the gas bottles 122 individually to the gas mixing part 124.

The gas mixing part 124 comprises a number of MFC 125 respectively installed at the number of single gas supply pipes 123 to respectively control the flow of the gas supplied through the single gas supply pipe 123, and a gas mixing unit 126 for mixing the number of single gases flow controlled through the number of MFCs 125 to reaction gases.

The gas supply part 132 comprises a first mixed gases supply pipe 127 for supplying the reaction gases mixed in the gas mixing unit 126 to one side of the furnace 110, a second mixed gases supply pipe 128 for supplying the reaction gases mixed in the gas mixing unit 126 to the other side of the furnace 110, and mixed gases flow control units installed at the first and the second mixed gases supply pipes 127 and 128, respectively, to control the flow of the mixed gases supplied through the first and the second mixed gases supply pipes 127 and 128.

The first mixed gases supply pipe 127 has one end connected to one side of the gas mixing unit 126 to supply the reaction gases mixed in the gas mixing unit 126 to one side of the furnace 110, and the other end connected to one side of the furnace 110.

Likewise, the second mixed gases supply pipe 128 has one end connected to the other side of the gas mixing unit 126 to supply the reaction gases mixed in the gas mixing unit 126 to the other side of the furnace 110, and the other end connected to the other side of the furnace 110.

In addition, the mixed gases flow control units comprise open/close valves 129 installed individually at the first and the second mixed gases supply pipes 127 and 128 for selectively opening/closing the first and the second mixed gases supply pipes 127 and 128 to selectively block the mixed gases supplied through the first and the second mixed gases supply pipes 127 and 128 depending upon the progress of the process. Flow control valves 130 are installed individually at the first and the second mixed gases supply pipes 127 and 128 to control the supply flow of the mixed gases supplied through the first and the second mixed gases supply pipes 127 and 128, and MFMs 131 are installed individually at the first and the second mixed gases supply pipes 127 and 128 to measure the supply flow of the mixed gases supplied through the first and the second mixed gases supply pipes 127 and 128.

The flow control valve 130 is preferably installed as a needle valve, and the open/close valve 129 is preferably installed as a handle valve. The MFM 131 may employ a commercially available flowmeter such as an electronic flowmeter, a thermal mass flowmeter, etc., and preferably is installed between the flow control valve 130 and the furnace 110 to measure the flow of the mixed gases controlled by the flow control valve 131.

Hereinafter, operation and effects of the semiconductor device manufacturing apparatus 100 in accordance with the present invention as described hereinabove will be specifically described.

The wafers 90 that a prior process has completed are arranged and loaded sequentially on the wafer boat 170 located at the loading device 140.

When the loading of the wafers 90 is completed, the gate valve 150 is opened, and the wafer boat 170 located at the loading device 140 is moved to the inside of the furnace 110 by a wafer boat transfer system (not shown) or an operator (not shown).

When the movement of the wafer boat 170 is completed, the gate valve 150 is closed. Then, at the same time the gate valve 150 is closed, the vacuum pump 180 and the heater 160 cooperate to form certain process conditions of the inside of the furnace 110 suitable for the thin-film deposition process. That is to say, the vacuum pump 180 and the heater 160 change the inside of the furnace 110 to a predetermined temperature and a predetermined vacuum pressure and maintain them.

The plurality of pressure sensors 115 continuously sense the pressures in the inside of the furnace 110, and an operator recognizes a current pressure of the inside of the furnace 110 through the number of pressure sensors 115.

When the inside of the furnace 110 reaches certain process conditions suitable for the thin-film deposition, the predetermined reaction gases are supplied to one side and the other side of the inside of the furnace 110 by the gas supply unit 120.

As a result, the predetermined thickness of thin-film is deposited on the wafers 90 in the inside of the furnace 110 by the powder formed as the reaction gases supplied into the certain process condition are chemically dissolved.

Since the thin-film deposition process such as SiGe is very sensitive to the flow of the reaction gases, the semiconductor device manufacturing apparatus 100 in accordance with the present invention precisely controls the flow of the reaction gases using the above-mentioned gas supply unit 120.

Describing more specifically, the single reaction gases stored in the number of gas bottles 122 are supplied to the gas mixing unit 126 through the single gas supply pipe 123. The number of MFCs 125 installed respectively at the plurality of single gas supply pipes 123 control the flow of the number of single gases supplied through the plurality of single gas supply pipes 123 suitably for the progress of the process.

The single gases flow controlled through the MFC 125 are totally mixed in the gas mixing unit 126 and, after the mixing, are supplied to one side and the other side of the furnace 110 through the first and the second mixed gases supply pipes 127 and 128, respectively. At this time, the mixed gases supplied into the inside of the furnace 110 through the first and the second mixed gases supply pipes 127 and 128 are additionally flow controlled by the flow control valve 130 installed at the first and the second mixed gases supply pipes 127 and 128, respectively.

Since the MFMs 131 for measuring the flow of the mixed gases are installed at the first and the second mixed gases supply pipes 127 and 128, respectively, an operator can recognize the flow of the mixed gases measured by the MFMs 131 to control the flow of the mixed gases continuously supplied, thereby enabling the flow control of the mixed gases precisely.

In addition, since the flow control valves 130 and the MFMs 131 are installed at the first and the second mixed gases supply pipes 127 and 128, respectively, the flow of the mixed gases supplied to one side and the other side of the furnace 110 can be controlled individually.

As described above, the semiconductor device manufacturing apparatus in accordance with the present invention is provided with the first and the second mixed gases supply pipes for supplying the reaction gases to one side and the other side of the furnace, respectively, and the flow control valve and the MFM capable of controlling and measuring the flow are installed at the first and the second mixed gases supply pipes, respectively. Therefore, the semiconductor device manufacturing apparatus in accordance with the present invention is capable of precisely controlling the flow of the reaction gases supplied into the inside of the furnace, and controlling and monitoring individually the flow of the reaction gases supplied to one direction and the other direction.

While this invention has been described in connection with what is presently considered to be the most practical and preferred embodiment, it is to be understood that the invention is not limited to the disclosed embodiment, but on the contrary, it is intended to cover various modification within the spirit and the scope of the Invention, which is set forth in the appended claims.

1. A semiconductor device manufacturing apparatus comprising:
a furnace having a closed space for seating a wafer, wherein certain process conditions are produced to deposit a predetermined thin-film on an upper surface of the wafer;
a loading device located at one side of the furnace to load the wafer to an interior of the furnace;
a gate valve interposed between the furnace and the loading device to selectively open/close a pathway between the furnace and the loading device;
a heater installed at a surface of the furnace to heat the interior of the furnace;
a vacuum pump installed at one exterior surface of the furnace to maintain a pressure in the interior of the furnace;
a gas reservoir for inidividually storing various reaction gases supplied from an exterior of the furnace;
a gas mixing device connected to the gas reservoir to mix the various reaction gases supplied from the gas reservoir;
at least two mixed gases supply pipes connected to the gas mixing device to supply the reaction gases mixed in the gas mixing device in each of a plurality of directions in the furnace; and
a mixed gases flow control unit installed at the mixed gases supply pipes to control a flow of the reaction gases supplied through the mixed gases supply pipes.

2. The semiconductor device manufacturing apparatus according to claim 1, wherein the mixed gases flow control unit comprises a flow control valve installed at the mixed gases supply pipe to control the flow of the reaction gases, and a mass flow meter installed at the mixed gases supply pipe to measure the flow of the reaction gases.

3. The semiconductor device manufacturing apparatus according to claim 2, wherein the mixed gases flow control unit further comprises an open/close valve for selectively opening/closing the mixed gases supply pipe.

4. The semiconductor device manufacturing apparatus according to claim 2, wherein the mass flow meter is installed at the mixed gases supply pipe between the furnace and the flow control valve.

5. The semiconductor device manufacturing apparatus according to claim 4, wherein the flow control valve is a needle valve.

6. The semiconductor device manufacturing apparatus according to claim 1, wherein the interior of the furnace comprises a pressure sensor for measuring a pressure of the interior of the furnace.

7. The semiconductor device manufacturing apparatus according to claim 1, wherein the gas reservoir comprises a number of gas bottles for individually storing the various reaction gases supplied from the exterior of the furnace, and a number of single gas supply pipes for transmitting the reaction gases stored in the number of gas bottles to the gas mixing device, respectively.

8. The semiconductor device manufacturing apparatus according to claim 7, wherein the gas mixing device comprises a number of mass flow controllers individually installed at the number of single gas supply pipes to respectively control the flow of the reaction gases supplied through the single gas supply pipe, and a gas mixing unit for mixing the reaction gases flow controlled through the mass flow controller.

9. The semicondutor device manufacturing apparatus according to claim 1, wherein the gas mixing device mixes the various reaction gases with an even mixing ratio.

10. A gas supply unit comprising:
a gas reservoir, installed at one side of a chamber for a predetermined processing space, for individually storing various reaction gases;
a gas mixing device, connected to the gas reservoir, for mixing the various reaction gases supplied from the gas reservoir;
at least two mixed gases supply pipes, connected to the gas mixing device, for supplying the reaction gases mixed in the gas mixing device in each of a plurality of directions in the chamber; and
a mixed gases flow control unit, installed at the mixed gases supply pipe, for controlling a flow of the reaction gases supplied through the mixed gases supply pipe.

11. The gas supply unit according to claim 10, wherein the mixed gases flow control unit comprises a flow control valve installed at the mixed gases supply pipe to control the flow of the reaction gases, and a mass flow meter installed at the mixed gases supply pipe to measure the flow of the reaction gases.

12. The gas supply unit according to claim 11, wherein the mixed gases flow control unit comprises an open/close valve for selectively opening/closing the mixed gases supply pipe.

13. The gas supply unit according to claim 11, wherein the mass flow meter is installed at the mixed gases supply pipe between the chamber and the flow control valve.

14. The gas supply unit according to claim 11, wherein the flow control valve is a needle valve.

15. The gas supply unit according to claim 10, wherein the gas reservoir comprises a number of gas bottles for storing the various reaction gases supplied from the exterior of the gas supply unit individually, and a number of single gas supply pipes for transmitting the reaction gases stored in the number of gas bottles to the gas mixing device, respectively.

16. The gas supply unit according to claim 15, wherein the gas mixing device comprises a number of mass flow controllers individually installed at the number of single gas supply pipes to respectively control the flow of the reaction gases supplied through the single gas supply pipe, and a gas mixing unit for mixing the reaction gases flow controlled through the mass flow controller.

17. The gas supply unit according to claim 10, wherein the gas mixing device mixes the various reaction gases with an even mixing ratio.
